(19) United States
(12) Patent Application Publication
(10) Pub. No.: US 2019/0348344 A1
(43) Pub. Date: Nov. 14, 2019

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventors: Wen-Long LU, Kaohsiung (TW); Jen-Kuang FANG, Kaohsiung (TW)

(73) Assignee: Advanced Semiconductor Engineering, Inc., Kaohsiung (TW)

(21) Appl. No.: 15/974,547

(22) Filed: May 8, 2018

(51) Int. Cl. H01L 23/373; H01L 23/532; H01L 23/00; H01L 29/16; H01L 23/522

(52) U.S. Cl. CPC H01L 23/3736; H01L 23/53276; H01L 23/5226; H01L 29/1606; H01L 23/562

(57) ABSTRACT

A connection structure is provided. The connection structure includes an intermediate conductive layer, a first conductive layer and a second conductive layer. The intermediate conductive layer includes a first surface and a second surface opposite to the first surface. The intermediate conductive layer has a first coefficient of thermal expansion. The first conductive layer is in contact with the first surface of the intermediate conductive layer. The first conductive layer has a second CTE. The second conductive layer is in contact with the second surface of the intermediate conductive layer. The first conductive layer and the second conductive layer are formed of the same material. One of the first CTE and the second CTE is negative, and the other is positive.

### BACKGROUND

### 1. Technical Field

The present disclosure relates generally to a semiconductor device package and a method of manufacturing the same.

### 2. Description of the Related Art

As electrical power consumption increases in electronic integrated circuits, it is challenging to dissipate the heat generated by the electronic integrated circuits, and thus the heat would be accumulated in conductive traces or vias of the electronic integrated circuits. Because the electronic integrated circuits include a plurality components (e.g., dielectric layers, conductive traces or vias) formed of different materials, the CTE mismatch between the components would cause a warpage, which would render a delamination for an interface between the conductive traces/vias and the dielectric layers.

### SUMMARY

In one or more embodiments, a connection structure includes an intermediate conductive layer, a first conductive layer and a second conductive layer. The intermediate conductive layer includes a first surface and a second surface opposite to the first surface. The intermediate conductive layer has a first coefficient of thermal expansion (CTE). The first conductive layer is in contact with the first surface of the intermediate conductive layer. The first conductive layer has a second CTE. The second conductive layer is in contact with the second surface of the intermediate conductive layer. The first conductive layer and the second conductive layer are formed of the same material. One of the first CTE and the second CTE is negative, and the other is positive.

In one or more embodiments, a connection structure includes an intermediate conductive layer, a first conductive layer and a second conductive layer. The intermediate conductive layer includes a first surface and a second surface opposite to the first surface. The first conductive layer is in contact with the first surface of the intermediate conductive layer. The second conductive layer is in contact with the second surface of the intermediate conductive layer. The first conductive layer and the second conductive layer are formed of the same material. One of the first conductive layer and the intermediate conductive layer includes a 6-membered ring containing carbon atom.

### BRIEF DESCRIPTION OF THE DRAWINGS

Aspects of the present disclosure are best understood from the following detailed description when read with the accompanying Figures. It is noted that various features may not be drawn to scale, and the dimensions of the various features may be arbitrarily increased or reduced for clarity of discussion.

FIG. 1A illustrates a cross-sectional view of a connection structure in accordance with some embodiments of the present disclosure.

FIG. 1B illustrates a cross-sectional view of a connection structure in accordance with some embodiments of the present disclosure.

FIG. 2 illustrates a cross-sectional view of a substrate in accordance with some embodiments of the present disclosure.

FIG. 3A illustrates a cross-sectional view of a substrate in accordance with some embodiments of the present disclosure.

FIG. 3B illustrates a cross-sectional view of a substrate in accordance with some embodiments of the present disclosure.

FIG. 3C illustrates a cross-sectional view of a substrate in accordance with some embodiments of the present disclosure.

FIG. 4A illustrates a cross-sectional view of a semiconductor device package in accordance with some embodiments of the present disclosure.

FIG. 4B illustrates a cross-sectional view of a semiconductor device package in accordance with some embodiments of the present disclosure.

FIG. 5A illustrates a cross-sectional view of a semiconductor device package in accordance with some embodiments of the present disclosure.

FIG. 5B illustrates a cross-sectional view of a semiconductor device package in accordance with some embodiments of the present disclosure.

FIG. 6A, FIG. 6B, FIG. 6C, FIG. 6D, FIG. 6E, FIG. 6F and FIG. 6G illustrate a method of manufacturing a semiconductor device package in accordance with some embodiments of the present disclosure.

FIG. 7A and FIG. 7B illustrate various types of semiconductor package devices in accordance with some embodiments of the present disclosure.

Common reference numerals are used throughout the drawings and the detailed description to indicate the same or similar elements. The present disclosure will be readily understood from the following detailed description taken in conjunction with the accompanying drawings.

### DETAILED DESCRIPTION

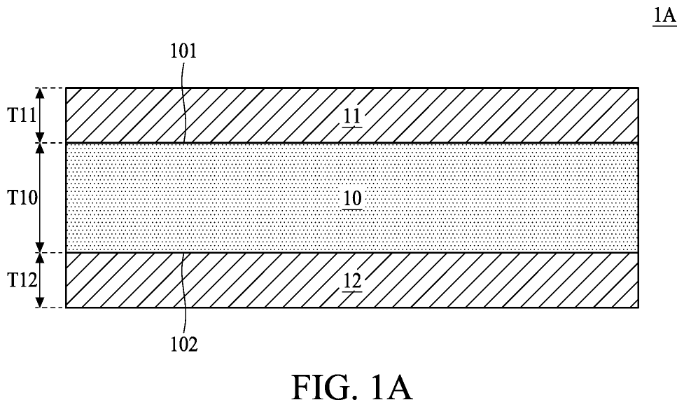

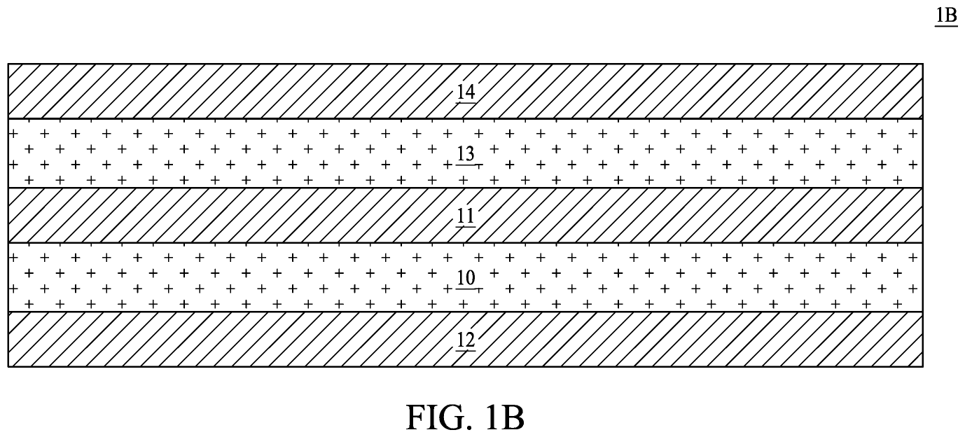

FIG. 1A illustrates a cross-sectional view of a connection structure 1A in accordance with some embodiments of the present disclosure. In some embodiments, the connection structure 1A can be a substrate (or a portion of the substrate), a leadframe (or a portion of the leadframe), a conductive trace, a conductive via or any other connection structures that can electrically connect one component or terminal to another component or terminal. The connection structure 1A includes conductive layers 10, 11 and 12.

The conductive layer 10 (also referred to as “an intermediate conductive layer”) is disposed between the conductive layers 11 and 12. For example, the conductive layer 10 is sandwiched by the conductive layers 11 and 12. The conductive layer 10 includes a surface 101 (also referred to as a first surface) and a surface 102 (also referred to as a second surface) opposite to the surface 101. The conductive layer 11 is disposed on the surface 101 of the conductive layer 10 and in contact with the surface 101 of the conductive layer 10. The conductive layer 12 is disposed on the surface 102 of the conductive layer 10 and in contact with the surface 102 of the conductive layer 10. In some embodiments, the conductive layer 11 and the conductive layer 12 are formed of the same material.

The conductive layer 10 includes a first coefficient of thermal expansion (CTE) and the conductive layers 11 and 12 include a second CTE. In some embodiments, one of the first CTE and the second CTE is negative and the other is positive. For example, the first CTE is negative and the second CTE is positive, and vice versa. In some embodiments, the first CTE is from about 7 ppm/° C. to about 20 ppm/° C. and the second CTE is from about −8 ppm/° C. to about −5 ppm/° C. Alternatively, the first CTE is from about −8 ppm/° C. to −5 ppm/° C. and the second CTE is from about 7 ppm/° C. to about 20 ppm/° C. In some embodiments, the conductive layer 10 is formed of a material including 6-membered ring containing carbon atoms (e.g., a basal plane constructed by a plurality of 6-membered rings) while the conductive layers 11 and 12 are formed of copper (Cu), gold (Au), silver (Ag), nickel (Ni), titanium (Ti), palladium (Pd) or its alloy. In other embodiments, the conductive layer 10 is formed of Cu, Au, Ag, Ni, Ti, Pd or its alloy while the conductive layers 11 and 12 are formed of the material including 6-membered ring containing carbon atoms. In some embodiments, the material including 6-membered ring containing carbon atoms is or includes graphene.

In some embodiments, a thickness T11 of the conductive layer 11 is substantially the same as a thickness T12 of the conductive layer 12. In the case that the first CTE is positive and the second CTE is negative, a relationship between the thickness T10 of the conductive layer 10 and the thickness T11 or T12 of the conductive layer 11 or 12 can be expressed by the following equation:

$$\frac{{T}_{11}}{{T}_{10}} ≅ \vert {CTE}_{10} / ( 2 \times {CTE}_{11} ) \vert , \qquad Eq . ( 1 )$$

where CTE₁₀ is the first CTE (i.e., the CTE of the conductive layer 10) and CTE₁₁ is the second CTE (i.e., the CTE of the conductive layer 11 or 12). In some embodiments, a ratio of the thickness T11 or T12 of the conductive layer 11 or 12 to the thickness T10 of the conductive layer 10 is in a range from about 1.75 to 8.

In the case that the first CTE is negative and the second CTE is positive, a relationship between the thickness T10 of the conductive layer 10 and the thickness T11 or T12 of the conductive layer 11 or 12 can be expressed by the following equation:

$$\frac{{T}_{10}}{{T}_{11}} ≅ \vert ( 2 \times {CTE}_{11} ) / {CTE}_{10} \vert , \qquad Eq . ( 2 )$$

where CTE₁₀ is the first CTE (i.e., the CTE of the conductive layer 10) and CTE₁₁ is the second CTE (i.e., the CTE of the conductive layer 11 or 12). In some embodiments, a ratio of the thickness T11 or T12 of the conductive layer 11 or 12 to the thickness T10 of the conductive layer 10 is in a range from about 0.43 to 2.

FIG. 1B illustrates a cross-sectional view of a connection structure 1B in accordance with some embodiments of the present disclosure. The connection structure 1B is similar to the connection structure 1A in FIG. 1A except that the connection structure 1B further includes conductive layers 13 and 14. In some embodiments, the conductive layer 13 and the conductive layer 10 are formed of the same material while the conductive layer 14 and the conductive layer 11 or 12 are formed of the same material. For example, the conductive layers 10 and 13 include a material with a positive CTE while the conductive layers 11, 12 and 14 include a material with a negative CTE, and vice versa. In some embodiments, the connection structure may include N layers, where N is an odd number and greater than 3. For example, N equals to (2n+1), where n is an integer. In the N-layer connection structure, any two adjacent conductive layers are formed of different materials, one having a positive CTE and the other having a negative CTE.

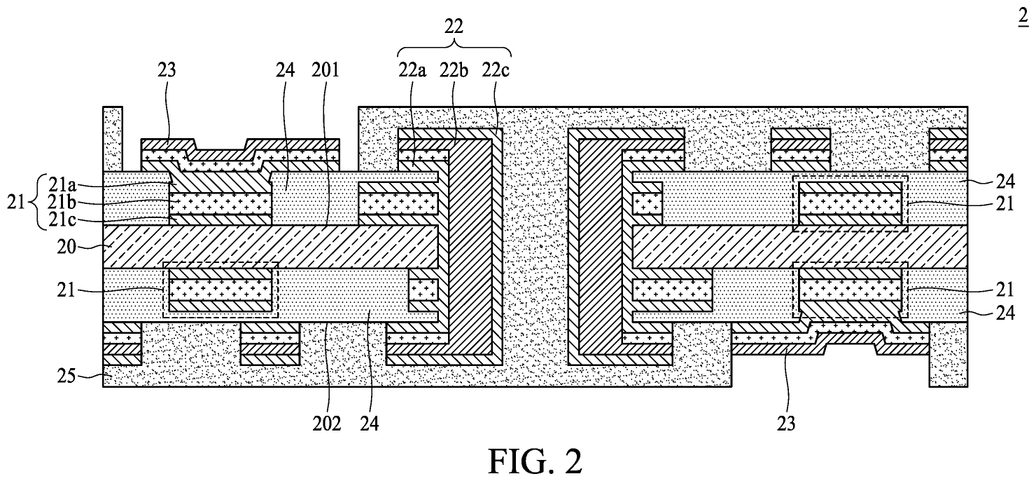

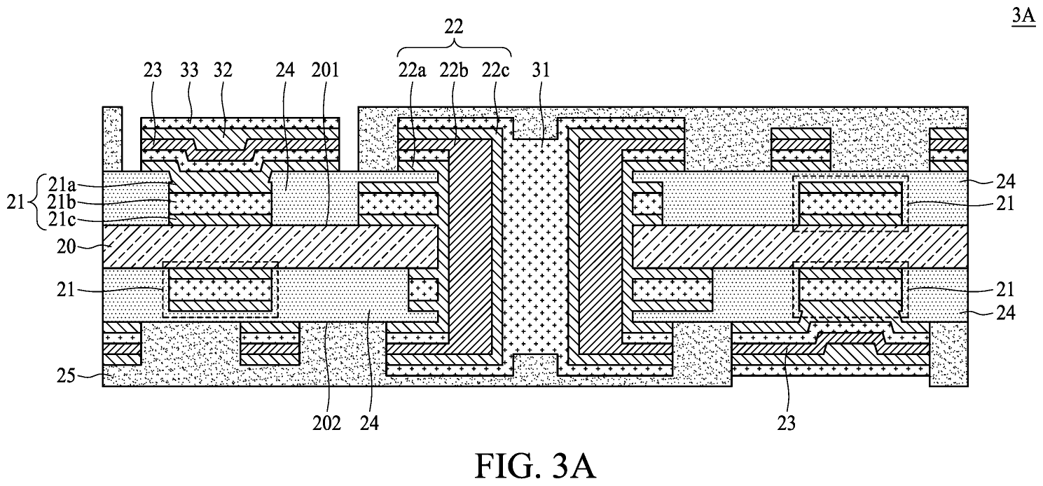

FIG. 2 illustrates a cross-sectional view of a substrate 2 in accordance with some embodiments of the present disclosure. The substrate 2 includes a dielectric layer 20, conductive traces 21, conductive vias 22, conductive contacts 23, a passivation layer 24 and a protection layer 25.

The dielectric layer 20 may include an organic component, such as a solder mask, a polyimide (PI), an epoxy, an Ajinomoto build-up film (ABF), a molding compound, a bismaleimide triazine (BT), a polybenzoxazole (PBO), a polypropylene (PP) or an epoxy-based material. The dielectric layer 20 may include inorganic materials, such as a silicon, a glass, a ceramic or a quartz. In some embodiments, the dielectric layer 20 is used as a core of the substrate 2. The dielectric layer 20 includes a surface 201 and a surface 202 opposite to the surface 201. In some embodiments, the dielectric layer 20 can be omitted to form a coreless substrate.

The conductive trances 21 are disposed on the surface 201 and/or the surface 202 of the dielectric layer 20. In some embodiments, the conductive traces 21 on the surface 201 of the dielectric layer 20 are symmetric to those on the surface 202 of the dielectric layer 20. Alternatively, the conductive traces 21 on the surface 201 of the dielectric layer 20 are asymmetric to those on the surface 202 of the dielectric layer 20. In some embodiments, the conductive trace 21 is similar to the connection structure 1A in FIG. 1A. For example, the conductive trace 21 includes a conductive layer 21b sandwiched by the conductive layers 21a and 21c. The conductive layer 21b is similar to the conductive layer 10 of the connection structure 1A in FIG. 1A while the conductive layers 21a and 21c are similar to the conductive layers 11 and 12 of the connection structure 1A in FIG. 1A. In other embodiments, the conductive trace 21 can include the connection structure 1B as shown in FIG. 1B or any other sandwiched connection structures depending on different design requirements.

The passivation layer 24 is disposed on the surface 101 and the surface 102 of the dielectric layer 20. The passivation layer 24 covers a portion of the conductive traces 21 and expose another portion of the conductive traces 21 for electrical connections. For example, the passivation layer 24 may include recesses to expose the portion of the conductive traces 21. In some embodiments, the passivation layer 24 includes silicon oxide, silicon nitride, gallium oxide, aluminum oxide, scandium oxide, zirconium oxide, lanthanum oxide or hafnium oxide.

The conductive contacts 23 are disposed on the passivation layer 24 and extend into recesses of the passivation layer 24 to be electrically connected to the exposed portion of the conductive traces 21. The conductive contacts 23 may be connected to solder balls for providing electrical connections between the substrate 2 and other circuits or components. For example, the conductive contacts 23 may be connected to a controlled collapse chip connection (C4) bump, a ball grid array (BGA) or a land grid array (LGA).

The conductive vias 22 are disposed on the passivation layer 24 and penetrate the passivation layer 24 to provide electrical connections between an upper surface of the substrate 2 and a lower surface of the substrate 2. In some embodiments, the conductive via 22 is similar to the connection structure 1A in FIG. 1A. For example, the conductive via 22 includes a conductive layer 22b sandwiched by the conductive layers 22a and 22c. The conductive layer 22b is similar to the conductive layer 10 of the connection structure 1A in FIG. 1A while the conductive layers 22a and 22c are similar to the conductive layers 11 and 12 of the connection structure 1A in FIG. 1A. In other embodiments, the conductive via 22 can include the connection structure 1B as shown in FIG. 1B or any other sandwiched connection structures depending on different design requirements. In some embodiments, the conductive vias 22 can be omitted (e.g., bland-via free substrate).

The protection layer 25 covers the dielectric layer 20, the conductive traces 21, the conductive vias 22 and the passivation layer 24 and exposes the conductive pads 23 for electrical connections. In some embodiments, the protection layer 25 may include organic materials, such as PI, epoxy, ABF, PP, molding compound or acrylic. The protection layer 25 may include inorganic materials, such as oxidation (SiOx, SiNx, TaOx), glass, silicon and ceramic.

In existing semiconductor device package, the conductive traces or vias include only a single conductive layer (which is usually a metal layer), and thus the heat generated by electronic components of the semiconductor device package would be accumulated in the conductive traces or vias. This would cause a warpage and delamination for an interface between the conductive traces/vias and the dielectric layers (or other layers formed of non-metal materials) due to the CTE mismatch therebetween. In accordance with the embodiments in FIG. 2, by using the connection structure 1A or 1B in FIG. 1A or 1B (e.g., a multi-layer structures, in which any two adjacent conductive layers are formed of different materials, one having a positive CTE and the other having a negative CTE) as conductive traces 21 and conductive vias 22 of the substrate 2, the conductive traces 21 or the conductive vias 22 would be in a strain balance situation even if the heat is accumulated therein, which would avoid the warpage and delamination for an interface between the conductive traces 21/conductive vias 22 and the dielectric layer 20/the passivation layer 24/the protection layer 25. In addition, the conductive traces 21 and the conductive vias 22 may include graphene, which would facilitate the heat dissipation and reduce the heat accumulated in the conductive traces 21 and the conductive vias 22.

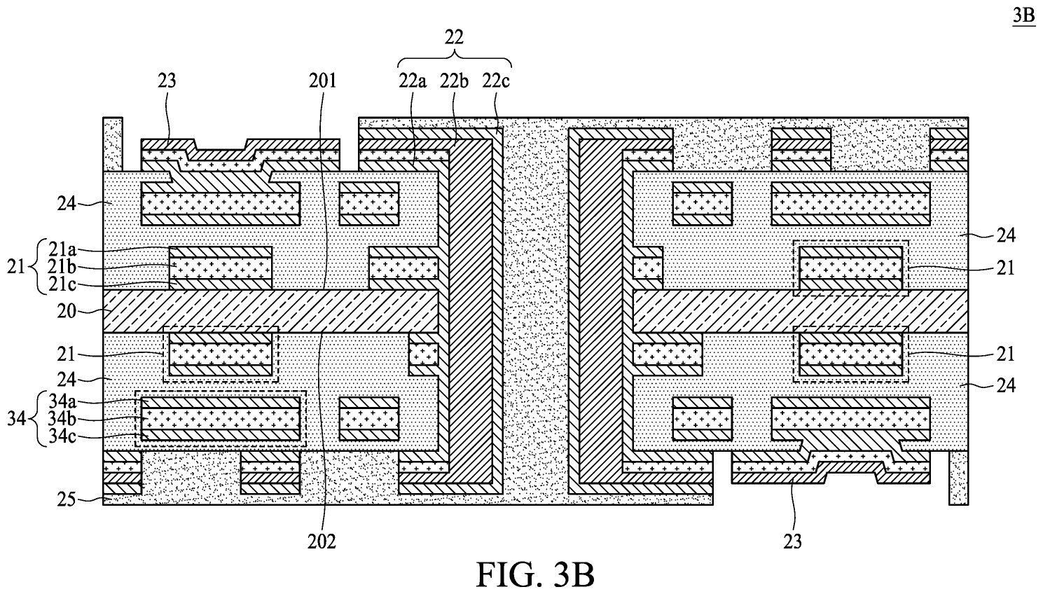

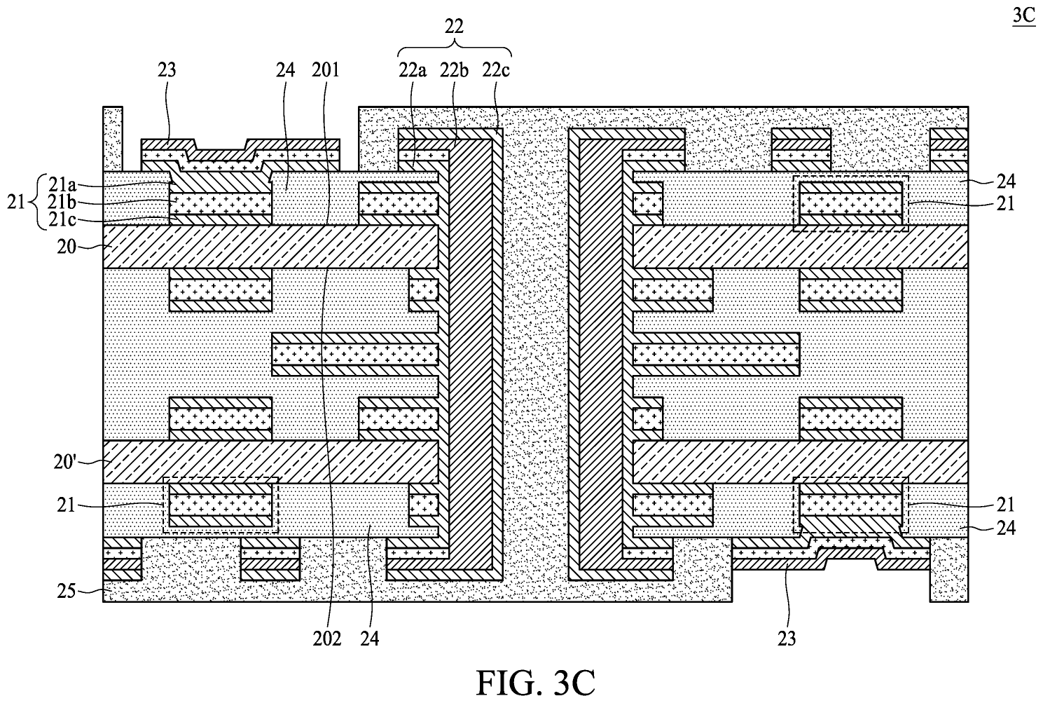

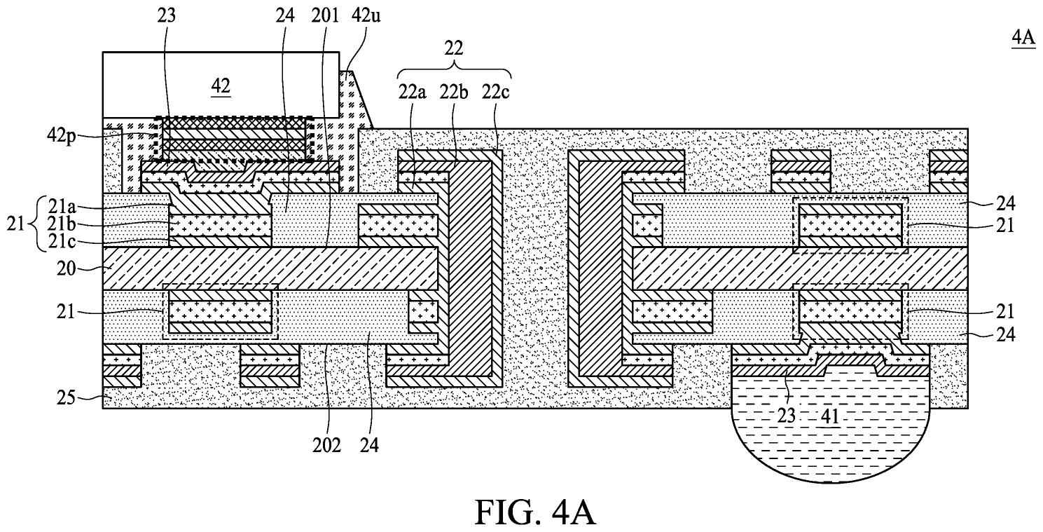

FIG. 3A illustrates a cross-sectional view of a substrate 3A in accordance with some embodiments of the present disclosure. The substrate 3A is similar to the substrate 2 in FIG. 2 one of the differences therebetween is that the substrate 3A further includes a through via 31 penetrating the protection layer 25. The through via 31 is electrically connected to the conductive vias 22. Another difference between the substrate 3A and the substrate 2 is that the substrate 30A further includes a graphene layer 32 disposed on the conductive contact 23 and a metal layer 33 disposed on the graphene layer 32.

FIG. 3B illustrates a cross-sectional view of a substrate 3B in accordance with some embodiments of the present disclosure. The substrate 3B is similar to the substrate 2 in FIG. 2 except that the substrate 3B further includes conductive traces 34. In other words, the substrate 3B include multiple conductive traces (or redistribution layers, RDL) 21, 34. The conductive trace 34 is disposed within the passivation layer 24 and spaced apart from the conductive trace 21. In some embodiments, the conductive trace 34 is similar to the connection structure 1A in FIG. 1A. For example, the conductive trace 34 includes a conductive layer 34b sandwiched by the conductive layers 34a and 34c. The conductive layer 34b is similar to the conductive layer 10 of the connection structure 1A in FIG. 1A while the conductive layers 34a and 34c are similar to the conductive layers 11 and 12 of the connection structure 1A in FIG. 1A. In other embodiments, the conductive trace 34 can include the connection structure 1B as shown in FIG. 1B or any other sandwiched connection structures depending on different design requirements.

FIG. 3C illustrates a cross-sectional view of a substrate 3C in accordance with some embodiments of the present disclosure. The substrate 3C is similar to the substrate 2 in FIG. 2 except that the substrate 3C includes multiple dielectric layers 20 and 20′ and multiple conductive traces. In some embodiments, the number of the layers of the dielectric layer or the conductive traces can be changed depending on different design requirements.

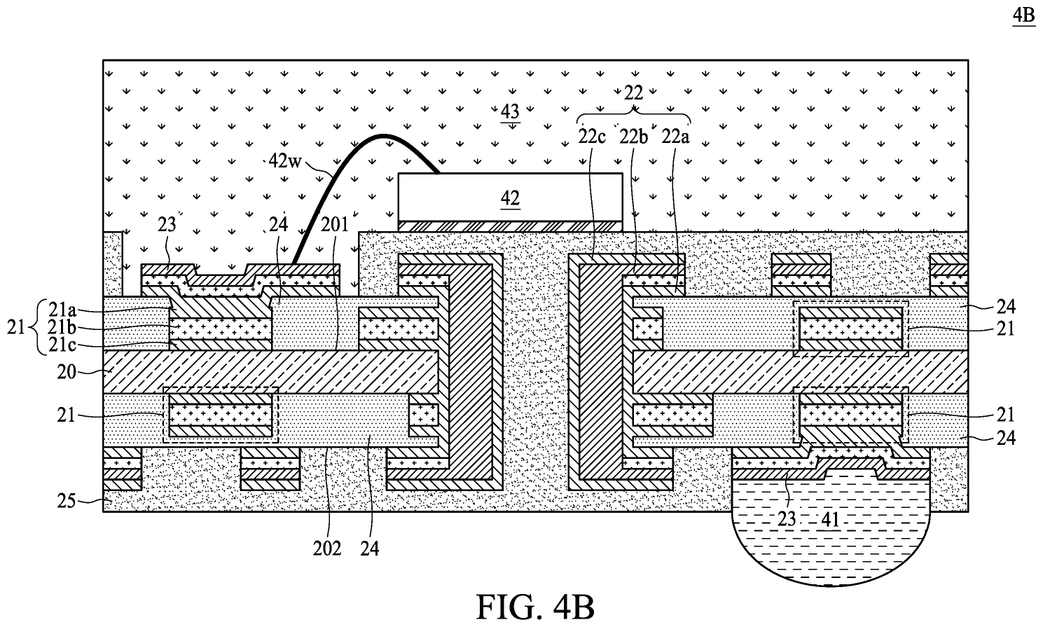

FIG. 4A illustrates a cross-sectional view of a semiconductor device package 4A (or a portion of the semiconductor device package 4A) in accordance with some embodiments of the present disclosure. The semiconductor device package 4A includes the substrate 2 as shown in FIG. 2, an electronic component 42 and an electrical contact 41. In some embodiments, the substrate 2 can be replaced by any of the substrates 3A, 3B and 3C in FIGS. 3A, 3B and 3C or any other substrate 2 with similar structures.

The electronic component 42 is disposed on the substrate 2 and electrically connected to the conductive contact 23. As shown in FIG. 4A, the electronic component 42 can be electrically connected to the conductive contact 23 through an electrical contact 42p by flip-chip technique. In some embodiments, the electronic component 42 can be electrically connected to the conductive contact 23 through a conductive wire 42w by wire bonding technique as shown in FIG. 4B, which illustrates a cross-sectional view of a semiconductor device package 4B in accordance with some embodiments of the present disclosure. The electronic component 42 may include a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof.

In some embodiments, as shown in FIG. 4A, an underfill 42u may be disposed between the substrate 2 and the electronic component 42 to cover the active surface of the electronic component 42. In some embodiments, the underfill 42u includes an epoxy resin, a molding compound (e.g., an epoxy molding compound or other molding compound), a polyimide, a phenolic compound or material, a material including a silicone dispersed therein, or a combination thereof. In some embodiments, the underfill 42u may include a capillary underfill (CUF) or a molded underfill (MUF). In some embodiments, the semiconductor device package 4A may include a graphene layer on the electronic component 42 to facilitate the heat dissipation of the semiconductor device package 4A.

In some embodiments, a package body 43 may be disposed on the substrate 2 to fully cover the electronic component 42 as shown in FIG. 4B. In some embodiments, the package body 43 includes, for example, organic materials (e.g., a molding compound, a BT, a PI, a PBO, a solder resist, an ABF, a PP or an epoxy-based material), inorganic materials (e.g., a silicon, a glass, a ceramic or a quartz), liquid and/or dry-film materials or a combination thereof. In some embodiments, the semiconductor device package 4B may include a graphene layer on the package body 43 to facilitate the heat dissipation of the semiconductor device package 4B.

The electrical contact 41 is disposed on a surface of the substrate 2 opposite to the surface on which the electronic component 42 is disposed. The electrical contact 41 is electrically connected to the conductive contact 23. In some embodiments, the electrical contact 41 includes a C4 bump, a BGA or an LGA.

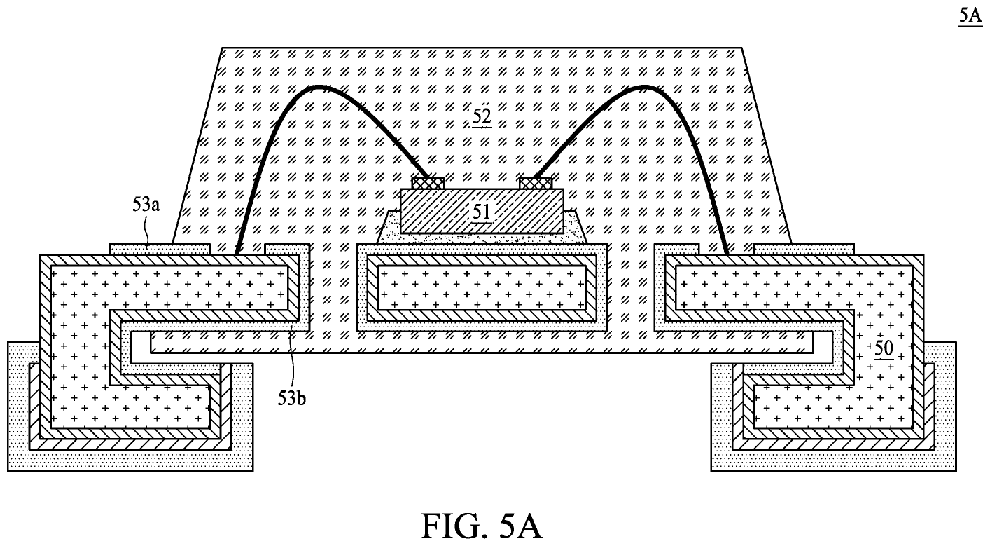

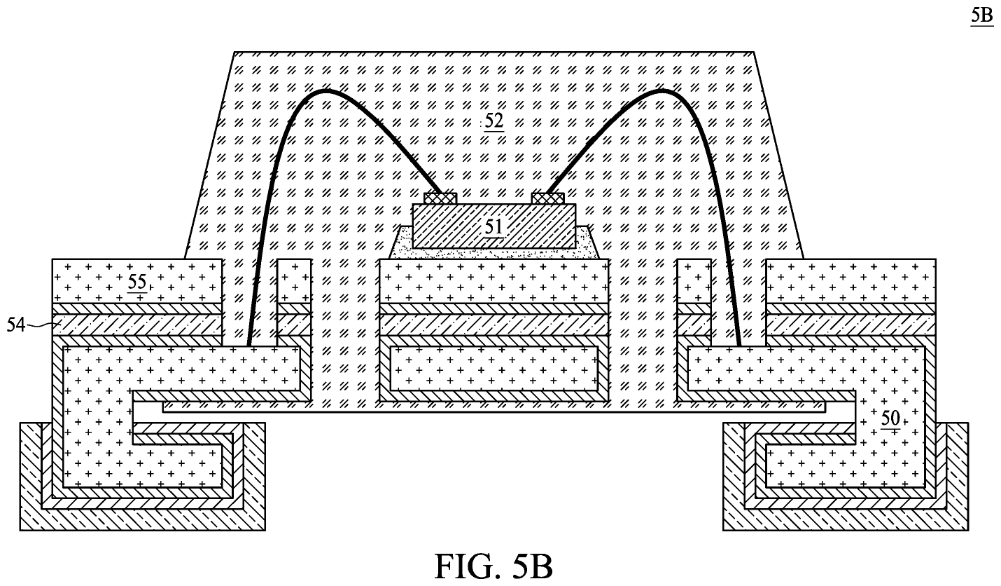

FIG. 5A illustrates a semiconductor device package 5A in accordance with some embodiments of the present disclosure. The semiconductor device package 5A includes a leadframe 50, an electronic component 51, a package body 52, graphene layers 53a, 52b and a protection layer 54. The electronic component 51 is disposed on the leadframe 50 and the package body covers the electronic component 51. The graphene layer 53a is disposed on a top surface of the leadframe 50 and the graphene layer 53b is disposed on a bottom surface of the leadframe 50. In some embodiments, a thickness of the graphene layer 53a or 53b is in a range from about 0.2 micrometer to about 1.5 micrometer. The graphene layers 53a and 53b can be used to facilitate the heat dissipation of the semiconductor device package 5A. In addition, since the graphene layers 53a, 53b include a negative CTE and the leadframe 50 is formed of a material with a positive CTE, they would be in a strain balance situation even if the heat is accumulated therein, which would avoid the warpage and delamination for an interface between the leadframe 50 and the package body 52.

FIG. 5B illustrates a semiconductor device package 5B in accordance with some embodiments of the present disclosure. The semiconductor device package 5B is similar to the semiconductor device package 5A in FIG. 5A except that the semiconductor device package 5B includes a graphene layer 54 disposed on the top surface of the leadframe 50 and a conductive layer 55 disposed on the graphene layer 54. In some embodiments, the conductive layer 55 includes or is formed of a material with a positive CTE. In some embodiments, the conductive layer 55 and the leadframe 50 are formed of the same material.

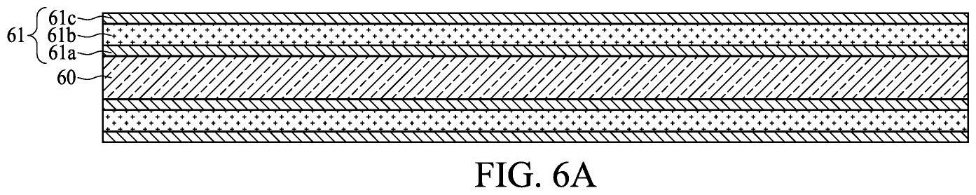

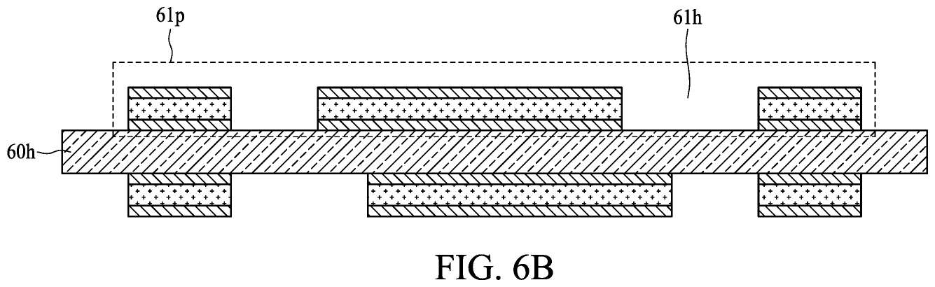

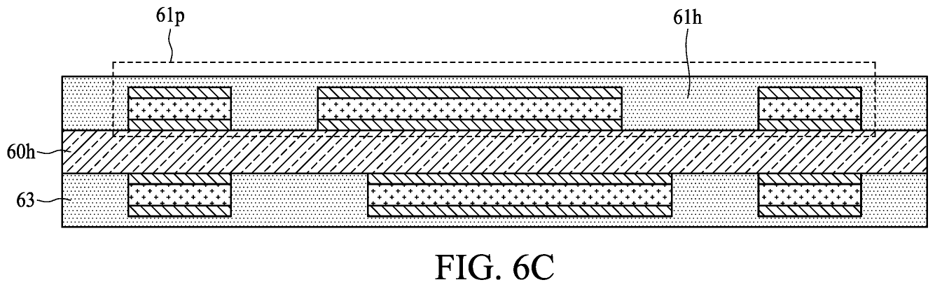

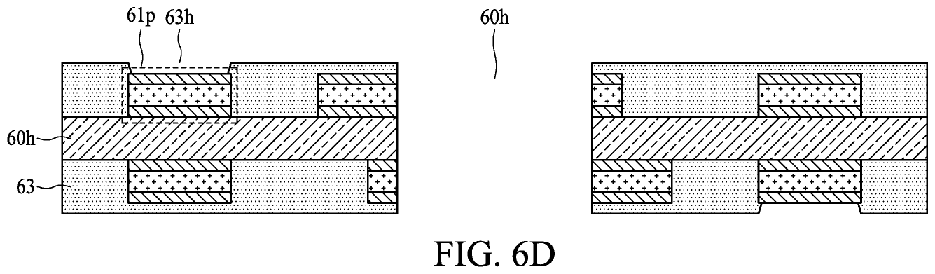

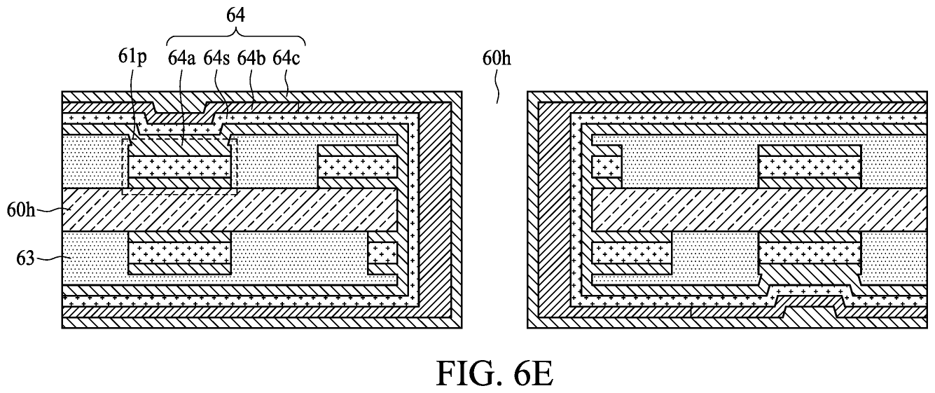

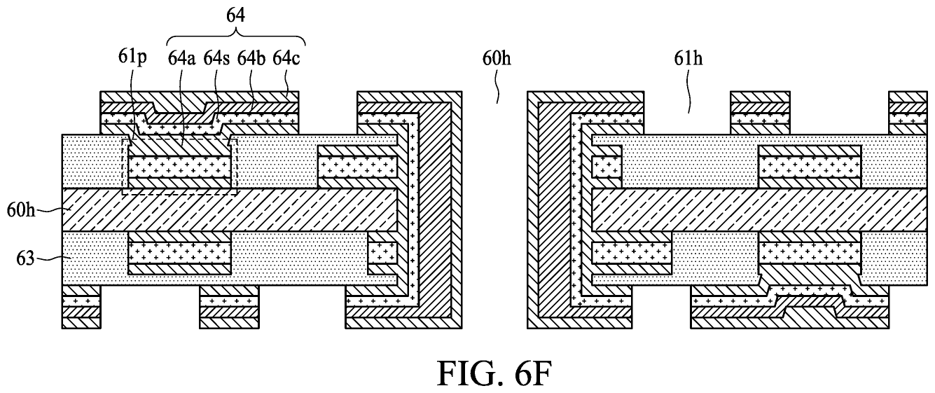

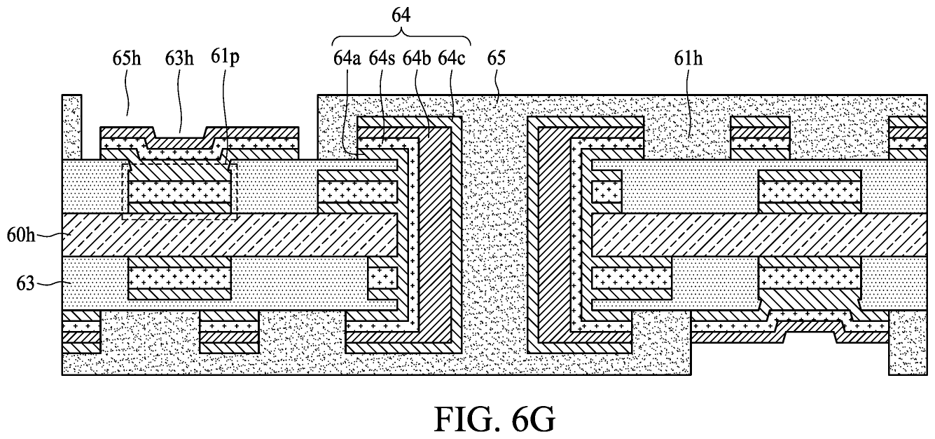

FIGS. 6A, 6B, 6C, 6D, 6E, 6F and 6G are cross-sectional views of a semiconductor device package at various stages of fabrication, in accordance with some embodiments of the present disclosure. Various figures have been simplified to provide a better understanding of the aspects of the present disclosure. In some embodiments, the structures shown in FIGS. 6A, 6B, 6C, 6D, 6E, 6F and 6G are used to manufacture the semiconductor device package 2 shown in FIG. 2. Alternatively, the structures shown in FIGS. 6A, 6B, 6C, 6D, 6E, 6F and 6G can be used to manufacture other semiconductor device packages.

Referring to FIG. 6A, a carrier 60 is provided. The carrier 60 can be a BT, an ABF, a FR4 or any other suitable materials. A graphene layer 61a is formed on both surfaces of the carrier 60 by, for example, chemical vapor deposition (CVD) or physical vapor deposition (PVD). A metal layer 61b is formed on the graphene layer 61a by, for example, plating. A graphene layer 61b is then formed on the metal layer 61b by, for example, CVD or PVD to form a connection structure 61. In some embodiments, the connection structure 61 is similar to the connection structure 1A in FIG. 1A.

Referring to FIG. 6B, a portion of the connection structure 61 is removed to form a plurality of openings 61h to expose both surfaces of the carrier 60. For example, the operation in 6B is to form patterned conductive traces 61p on the carrier 60. In some embodiments, the conductive traces 61p are formed by the following operations: (i) forming a photoresist or mask on the metal layer 61c; (ii) defining a predetermined pattern on the photoresist or mask by, for example, lithographic technique (e.g., exposure); (iii) developing the photoresist or mask to expose a portion of the connection structure 61; and (iv) removing the portion of the connection structure 61 exposed from the photoresist or mask by, for example, etching technique.

Referring to FIG. 6C, a passivation layer 63 is formed on the carrier 60 to cover the carrier 60 and the conductive traces 61p. In some embodiments, the passivation layer 63 is formed by lamination and/or lithographic techniques.

Referring to FIG. 6D, a portion of the passivation layer 63 is removed to expose a portion of the conductive traces 61p. In some embodiments, the portion of the passivation layer 63 is removed by, for example, developing and/or etching. A portion of the passivation layer 63, the conductive traces 61p and the carrier 60 are then removed to form a through hole 60h. In some embodiments, the through hole 60h is formed by drilling or laser drilling.

Referring to FIG. 6E, a graphene layer 64a is formed on the exterior surface of the passivation layer 63 and extends into the opening 63h to be electrically connected to the exposed portion of the conductive traces 61p. The graphene layer 64a is also formed on sidewalls of the through hole 60h. In some embodiments, the graphene layer 64a is formed by CVD or PVD. A seed layer 64s is formed on the graphene layer 64a by, for example, electroplating, electroless plating, sputtering, paste printing, bumping or bonding. A metal layer 64b is formed on the seed layer 64s by, for example, plating. A graphene layer 64c is then formed on the metal layer 64b by, for example, CVD or PVD.

Referring to FIG. 6F, patterned conductive traces 64 are formed by removing a portion of the graphene layers 64a, 64c, the seed layer 64s and the metal layer 64b. In some embodiments, the conductive traces 64 are formed by the following operations: (i) forming a photoresist or mask on the graphene layer 64c; (ii) defining a predetermined pattern on the photoresist or mask by, for example, lithographic technique (e.g., exposure); (iii) developing the photoresist or mask to expose a portion of the graphene layer 64c; and (iv) removing the portion of the graphene layer 64c and the metal layer 64b, the seed layer 64s and the graphene layer 64a under the exposed portion of the graphene layer 64c by, for example, etching.

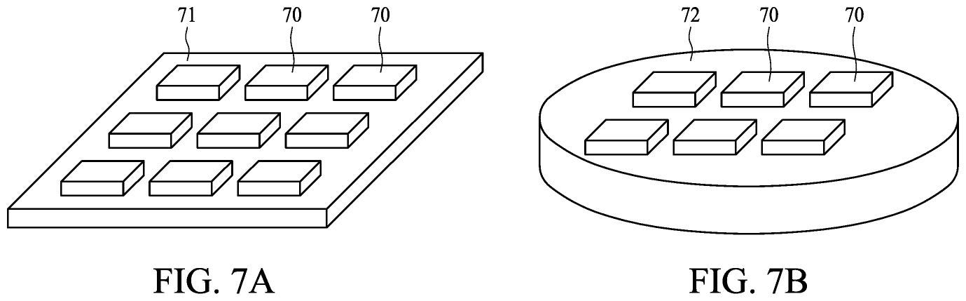

FIGS. 7A and 7B illustrate various types of semiconductor package devices in accordance with some embodiments of the present disclosure.

As shown in FIG. 7A, a plurality of chips 70 or dies are placed on a square-shaped carrier 71. In some embodiments, the carrier 71 may include organic materials (e.g., molding compound, BT, PI, PBO, solder resist, ABF, PP, epoxy-based material, or a combination of two or more thereof) or inorganic materials (e.g., silicon, glass, ceramic, quartz, or a combination of two or more thereof), or a combination of two or more thereof.

As shown in FIG. 7B, a plurality of chips 70 or dies are placed on a circle-shaped carrier 72. In some embodiments, the carrier 72 may include organic materials (e.g., molding compound, BT, PI, PBO, solder resist, ABF, PP, epoxy-based material, or a combination of two or more thereof) or inorganic materials (e.g., silicon, glass, ceramic, quartz, or a combination of two or more thereof), or a combination of two or more thereof.

As used herein, the terms “approximately,” “substantially,” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” or “about” the same if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

While the present disclosure has been described and illustrated with reference to specific embodiments thereof, these descriptions and illustrations do not limit the present disclosure. It can be clearly understood by those skilled in the art that various changes may be made, and equivalent components may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. A connection structure, comprising:
an intermediate conductive layer including a first surface and a second surface opposite to the first surface, the intermediate conductive layer having a first coefficient of thermal expansion (CTE);
a first conductive layer in contact with the first surface of the intermediate conductive layer, the first conductive layer having a second CTE;
a second conductive layer in contact with the second surface of the intermediate conductive layer,
wherein the first conductive layer and the second conductive layer are formed of the same material; and
wherein one of the first CTE and the second CTE is negative, and the other is positive.

2. The connection structure of claim 1, wherein one of the first conductive layer and the intermediate conductive layer includes 6-membered ring containing carbon atoms.

3. The connection structure of claim 1, wherein one of the first conductive layer and the intermediate conductive layer includes graphene.

4. The connection structure of claim 1, wherein a thickness of the first conductive layer is equal to a thickness of the second conductive layer.

5. The connection structure of claim 4, wherein
$$\frac{{t}_{g}}{{t}_{c}} ≅ \vert {CTE}_{c} / ( 2 \times {CTE}_{g )} \vert , \qquad$$
where t_{g} is a thickness of the first conductive layer, t_{c} is a thickness of the intermediate conductive layer, CTE_{c} is the first CTE and CTE_{g} is the second CTE; and
the second CTE is negative.

6. The connection structure of claim 4, wherein
the second CTE is negative; and
a ratio of a thickness of the first conductive layer to a thickness of the intermediate conductive layer is in a range from about 1.75 to about 8.

7. The connection structure of claim 4, wherein
$$\frac{{t}_{g}}{{t}_{c}} ≅ \vert ( 2 \times {CTE}_{c} ) / {CTE}_{g} \vert , \qquad$$
where t_{g} is a thickness of the intermediate conductive layer, t_{c} is a thickness of the first conductive layer, CTE_{g} is the first CTE and CTE_{c} is the second CTE; and
the first CTE is negative.

8. The connection structure of claim 4, wherein
the first CTE is negative; and
a ratio of a thickness of the first conductive layer to a thickness of the intermediate conductive layer is in a range from about 0.43 to about 2.

9. The connection structure of claim 1, wherein the intermediate conductive layer, the first conductive layer and the second conductive layer define a trace.

10. The connection structure of claim 1, wherein the intermediate conductive layer, the first conductive layer and the second conductive layer define a conductive via.

11. A connection structure, comprising:
an intermediate conductive layer including a first surface and a second surface opposite to the first surface;
a first conductive layer in contact with the first surface of the intermediate conductive layer;
a second conductive layer in contact with the second surface of the intermediate conductive layer,
wherein the first conductive layer and the second conductive layer are formed of the same material, and one of the first conductive layer and the intermediate conductive layer includes a 6-membered ring containing carbon atom.

12. The connection structure of claim 11, wherein one of the first conductive layer and the intermediate conductive layer includes a basal plane constructed by a plurality of 6-membered rings.

13. The connection structure of claim 11, wherein one of the first conductive layer and the intermediate conductive layer is with a negative CTE.

14. The connection structure of claim 13, wherein a thickness of the first conductive layer is equal to a thickness of the second conductive layer.

15. The connection structure of claim 14, wherein
the first conductive layer is with a negative CTE; and
a ratio of a thickness of the first conductive layer to a thickness of the intermediate conductive layer is in a range from about 1.75 to about 8.

16. The connection structure of claim 14, wherein
the intermediate conductive layer is with a negative; and
a ratio of a thickness of the first conductive layer to a thickness of the intermediate conductive layer is in a range from about 0.43 to about 2.

17. The connection structure of claim 13, wherein one of the first conductive layer and the intermediate conductive layer includes graphene.

18. The connection structure of claim 13, wherein the intermediate conductive layer, the first conductive layer and the second conductive layer define a trace.

19. The connection structure of claim 13, wherein the intermediate conductive layer, the first conductive layer and the second conductive layer define a conductive via.

20. The connection structure of claim 11, wherein the CTE of the first conductive layer is smaller than the CTE of the intermediate conductive layer.
